(19) United States
(12) Patent Application Publication
(10) Pub. No.: US 2013/0049123 A1
(43) Pub. Date: Feb. 28, 2013

(54) Semiconductor Device with DRAM Word Lines and Gate Electrodes in Non-Memory Regions of the Device Comprised of a Metal, and Methods of Making Same

(71) Applicants: Peter Baars, Dresden (DE); Christopher M. Prindle, Dresden (DE); Johannes F. Groschopf, Radebeul (DE)

(72) Inventors: Peter Baars, Dresden (DE); Christopher M. Prindle, Dresden (DE); Johannes F. Groschopf, Radebeul (DE)

(73) Assignee: GLOBALFOUNDRIES INC., Grand Cayman (KY)

(21) Appl. No.: 13/215,568

(22) Filed: Aug. 23, 2011

(51) Int. Cl. H01L 27/088; H01L 21/28

(52) U.S. Cl. 257/368; 438/591; 257/E21.19; 257/E29.255; 257/E27.06

(57) ABSTRACT

Generally, the present disclosure is directed to a semiconductor device with DRAM word lines and gate electrodes in a non-memory region of the device made of at least one layer of metal, and various methods of making such devices. One illustrative method disclosed herein involves forming a sacrificial gate electrode structure in a logic region of the device and a word line in a memory array of the device, wherein the sacrificial gate electrode structure and the word line have a first layer of insulating material and at least one first layer comprising a metal, removing the sacrificial gate electrode structure in the logic region to define a gate opening and forming a final gate electrode structure in the gate opening.

### BACKGROUND OF THE INVENTION

1. Field of the Invention

The present disclosure generally relates to the field of fabricating integrated circuits, and, more particularly, to a semiconductor device with DRAM word lines and gate electrodes in a non-memory region of the device made of at least one layer of metal, and various methods of making such devices.

2. Description of the Related Art

In modern integrated circuits, a very high number of individual circuit elements, such as field effect transistors in the form of CMOS, NMOS, PMOS elements, resistors, capacitors and the like, are formed on a single chip area. Typically, feature sizes of these circuit elements are steadily decreasing with the introduction of every new circuit generation, to provide currently available integrated circuits with high performance in terms of increase operating speed and/or reduced power consumption. A reduction in size of transistors is an important aspect in steadily improving device performance of complex integrated circuits, such as CPUs. The reduction in size commonly brings about an increased switching speed, thereby enhancing signal processing performance, while, however, increasing dynamic power consumption of the individual transistors. That is, due to the reduced switching time interval, the transient currents upon switching a MOS transistor element from logic low to logic high are significantly increased.

In addition to the large number of transistor elements, a plurality of passive circuit elements, such as capacitors, are typically formed in integrated circuits that are used for a plurality of purposes, such as charge storage for storing information, for decoupling and the like. Decoupling in integrated circuits is an important aspect for reducing the switching noise of the fast switching transistors, since the decoupling capacitor may provide energy at a specific point of the circuitry, for instance at the vicinity of a fast switching transistor, and thus reduce voltage variations caused by the high transient currents which may otherwise unduly affect the logic state represented by the transistor.

Due to the decreased dimensions of circuit elements, not only the performance of the individual transistor elements may be increased, but also their packing density may be improved, thereby providing the potential for incorporating increased functionality into a given chip area. For this reason, highly complex circuits have been developed, which may include different types of circuits, such as analog circuits, digital circuits and the like, thereby providing entire systems on a single chip (SoC). Furthermore, in sophisticated micro-controller devices and other sophisticated devices, an increasing amount of storage or memory capacity may be provided on or “embedded” in the chip with the CPU core, thereby also significantly enhancing the overall performance of modern computer devices.

Typical memory devices that are found in modern integrated circuit devices include static RAM (SRAM) memory devices and dynamic RAM (DRAM) memory devices. Typically, the choice as to which type of memory device to use on a given integrated circuit device depends upon multiple factors, such as, for example, available die space, the desired access speed for accessing the memory device, the overall amount of memory needed, available power budgets, etc. A single integrated circuit device may have multiple types of such memory devices in an effort to produce the most cost-effective device that meets product specifications. For example, a SRAM cell is typically comprised of six individual transistors, a single capacitor and associated contacts, whereas a typical DRAM cell has a bit line, a word line, a single transistor, a single capacitor and associated contacts. A SRAM cell tends to have a faster access time than a DRAM cell, but a SRAM cell consumes more plot space on a chip thereby significantly reducing the information storage density for SRAM memories as compared to DRAM memories. Thus, a higher information storage density may be achieved with DRAMs, although at a reduced access time compared to SRAMs, which may nevertheless render DRAMs attractive in complex semiconductor devices.

There is always a constant drive to reduce the physical size of integrated circuit devices, and it is even more prevalent today given the enormous increase in portable consumer products, such as cell phones, where the physical size of the consumer product itself is continually reduced. Despite the aforementioned reductions in size of such products, consumers demand ever increasing levels of performance. As a result, integrated circuit devices are continually reduced in size while, at the same time, the performance of the integrated circuit device must be increased even though there is less plot space available. In some cases, this results in embedding memory on a chip such that the device contains both logic circuits and memory devices. All of the foregoing means that device designers are constantly trying to reduce the physical size of various components of the integrated circuit device, such as pitch between word lines and bit lines on a DRAM cells, while maintaining or increasing the ultimate overall performance capability of the integrated circuit device, i.e., the chip.

As noted previously, complex integrated circuit devices typically include a memory array, such as an embedded DRAM array, and other non-memory circuits, e.g., logic circuits (such as microprocessors), located outside of the memory array. One problem associated with manufacturing such complex devices is that some designers and manufacturing engineers tend to treat the regions outside the memory array and the memory array itself as completely separate items, each with their own unique design rules and process flows. As a result, in some cases, manufacturing such complex devices is not as cost-effective or efficient as it could be. For example, by independently focusing on one region to the exclusion of the other, additional manufacturing operations may be performed only in that one region, which tends to require additional manufacturing time, makes the resulting device more costly, and may lead to decreased product yields.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a semiconductor device with DRAM word lines and gate electrodes in a non-memory region of the device made of at least one layer of metal, and various methods of making such devices.

One illustrative method disclosed herein forming a sacrificial gate electrode structure in a logic region of the device and a word line in a memory array of the device, wherein the sacrificial gate electrode structure and the word line have a first layer of insulating material and at least one first layer comprising a metal, removing the sacrificial gate electrode structure to define a gate opening and forming a final gate electrode structure in the gate opening.

One illustrative semiconductor device disclosed herein includes a word line in a memory array of the device and a replacement gate electrode structure in a logic region of the device, wherein the word line includes a first layer of insulating material and at least one first layer comprising a metal. In this embodiment, the replacement gate electrode structure includes a conformally deposited second layer of insulating material and a conformally deposited second layer comprising a metal positioned on the second layer of insulating material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1O depict illustrative methods that may be employed as described herein in manufacturing all or part of the illustrative semiconductor device described herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

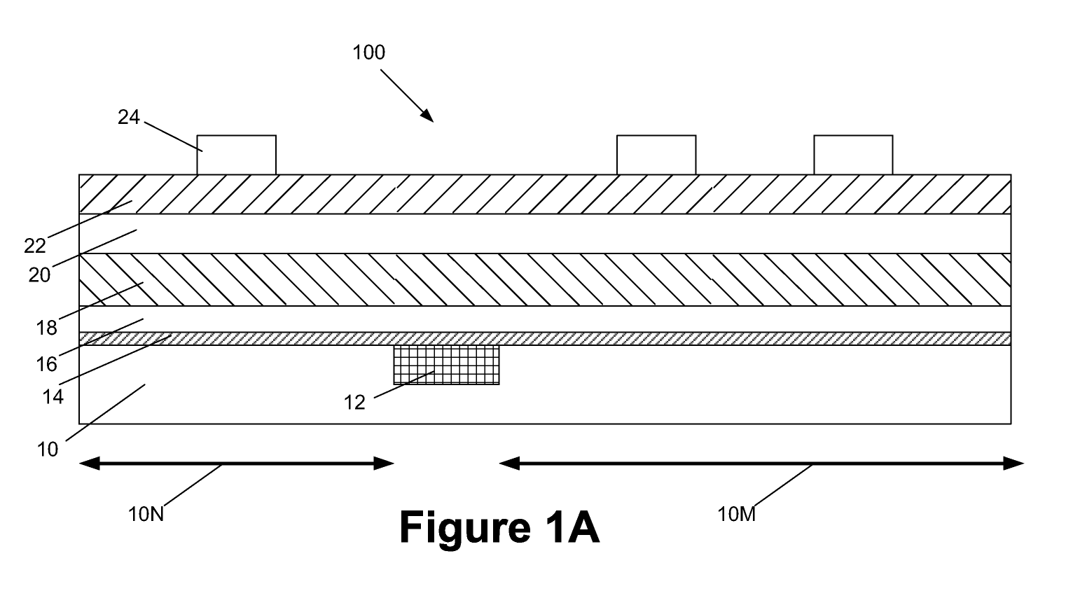

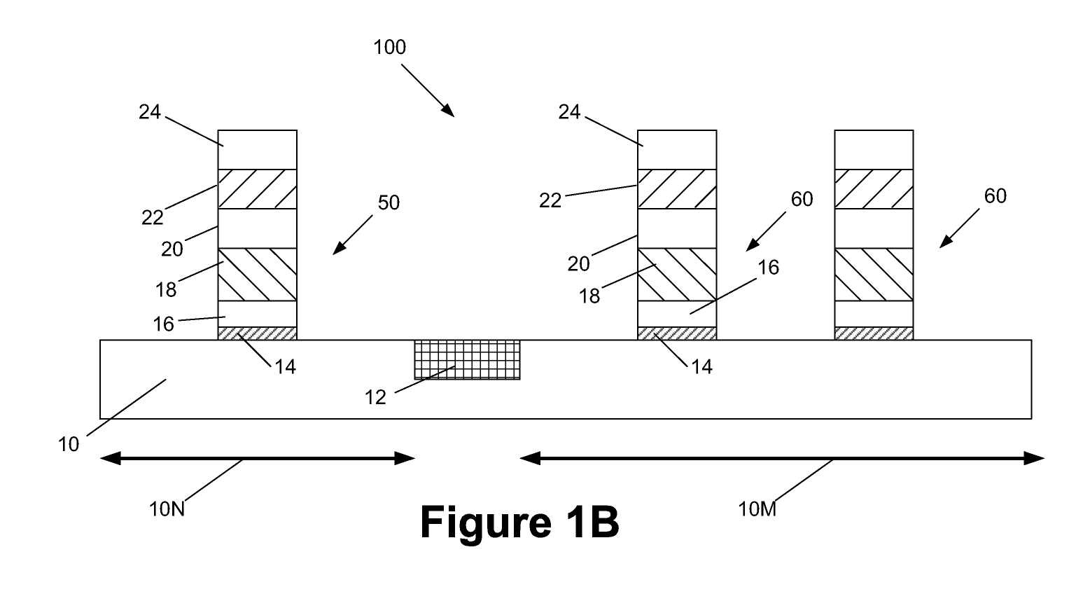

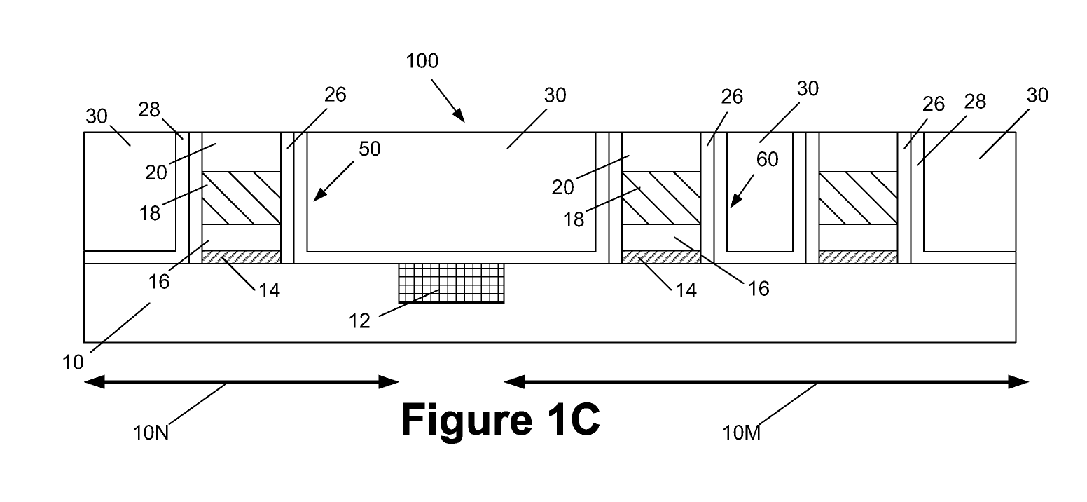

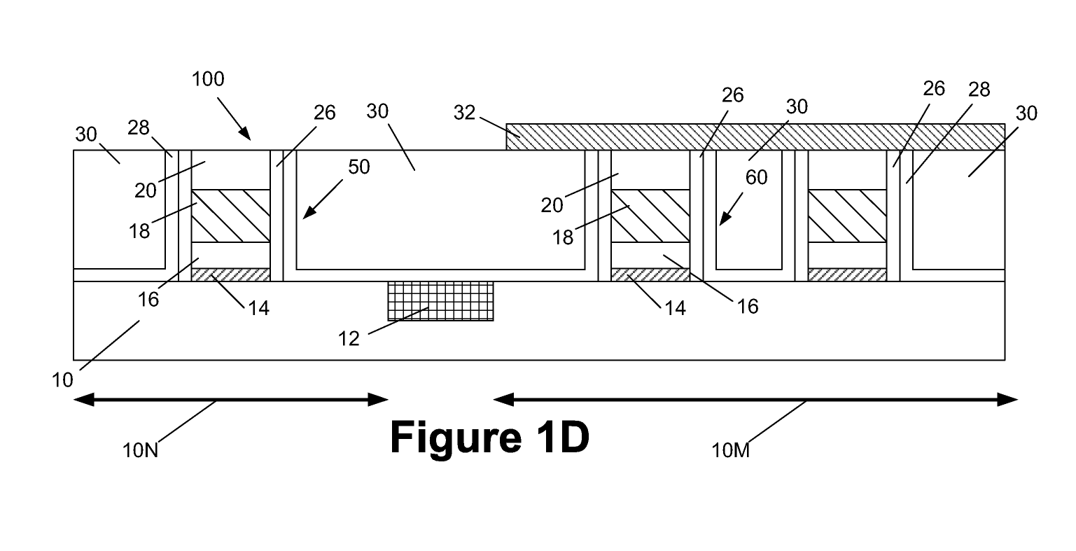

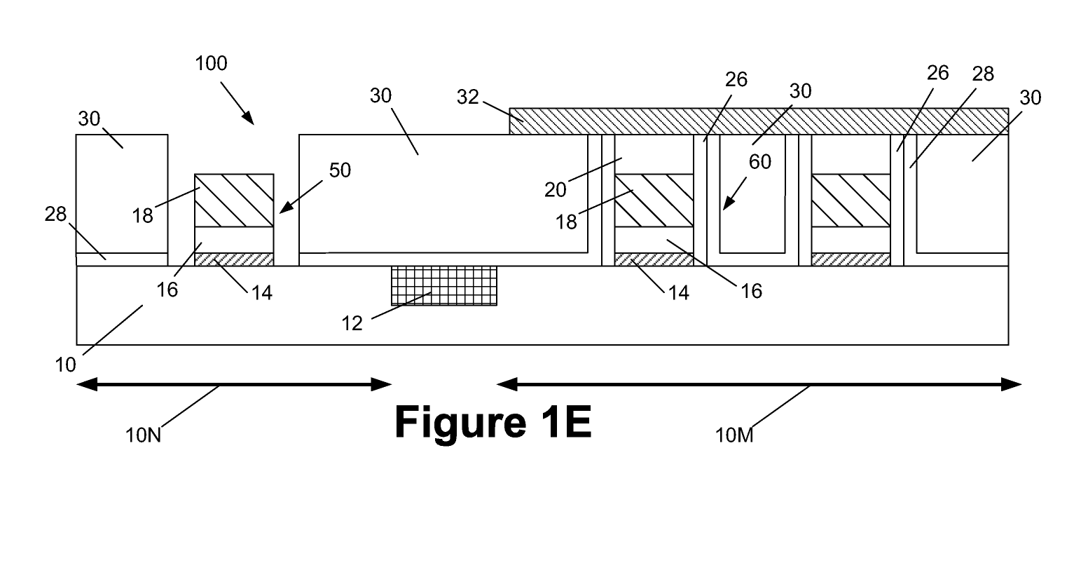

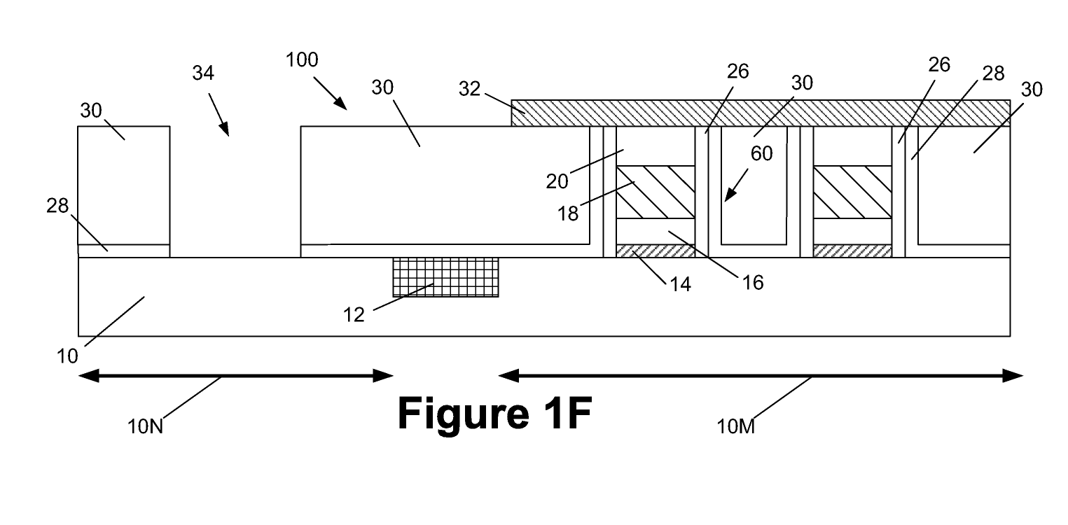

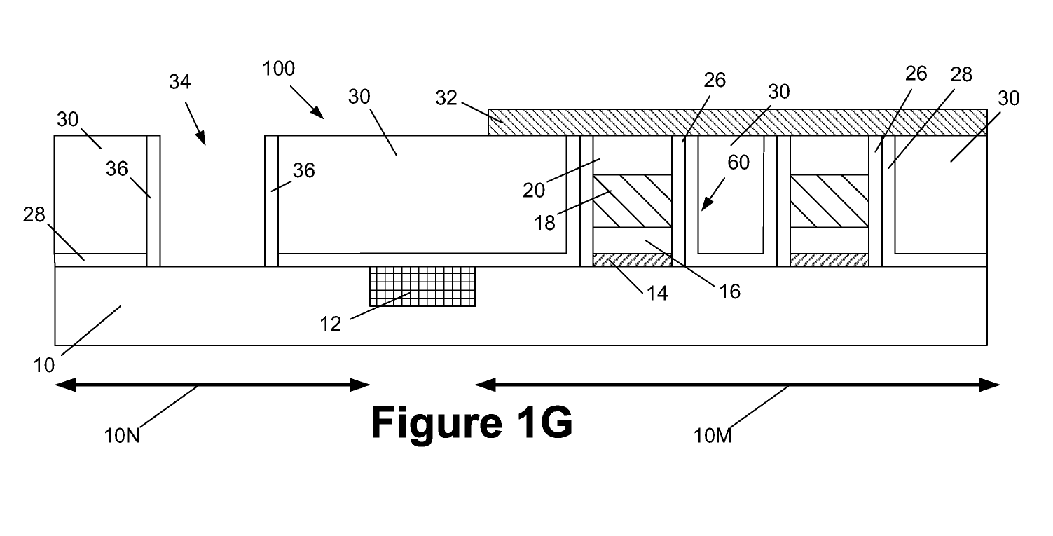

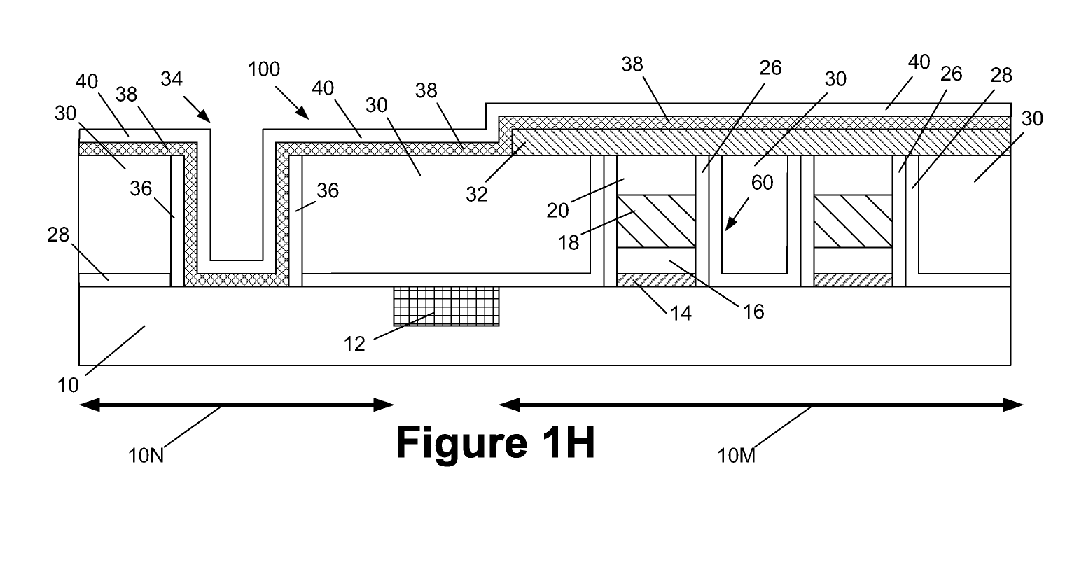

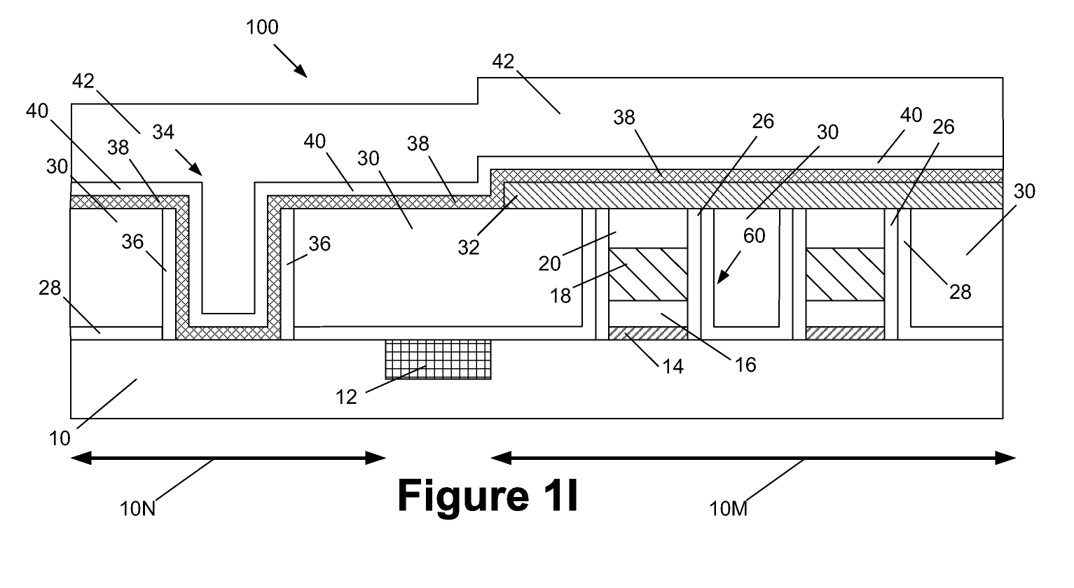

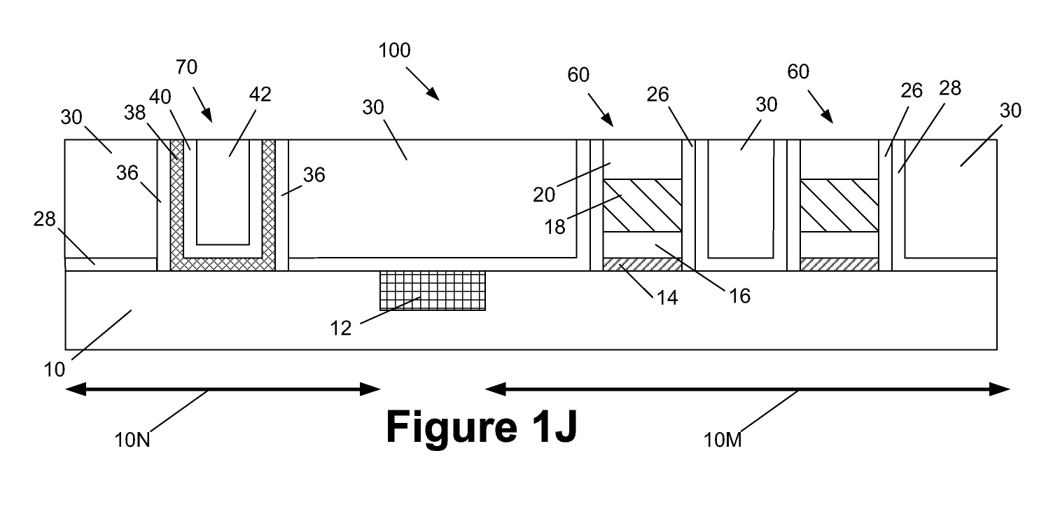

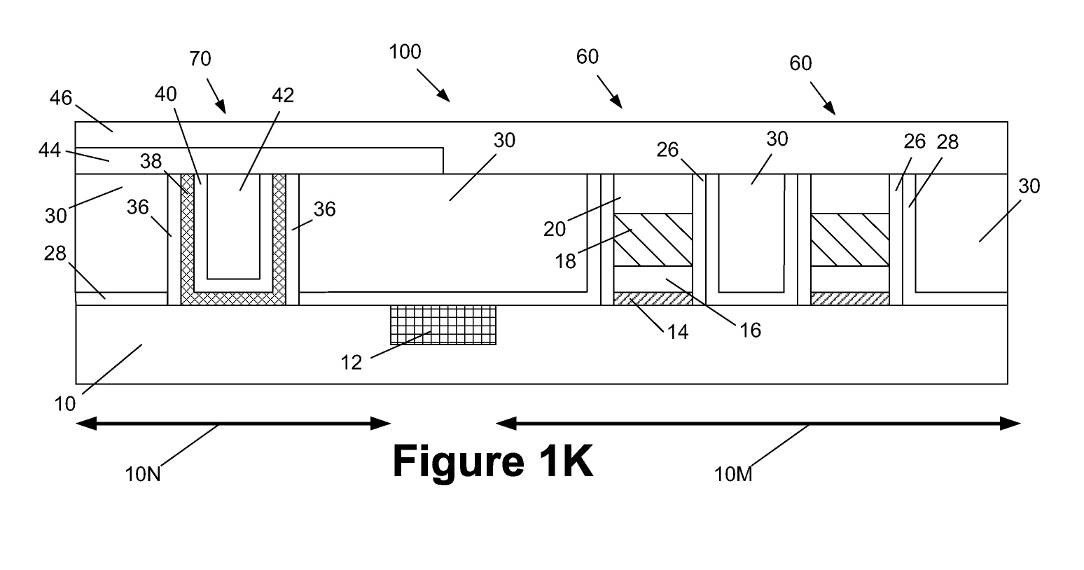

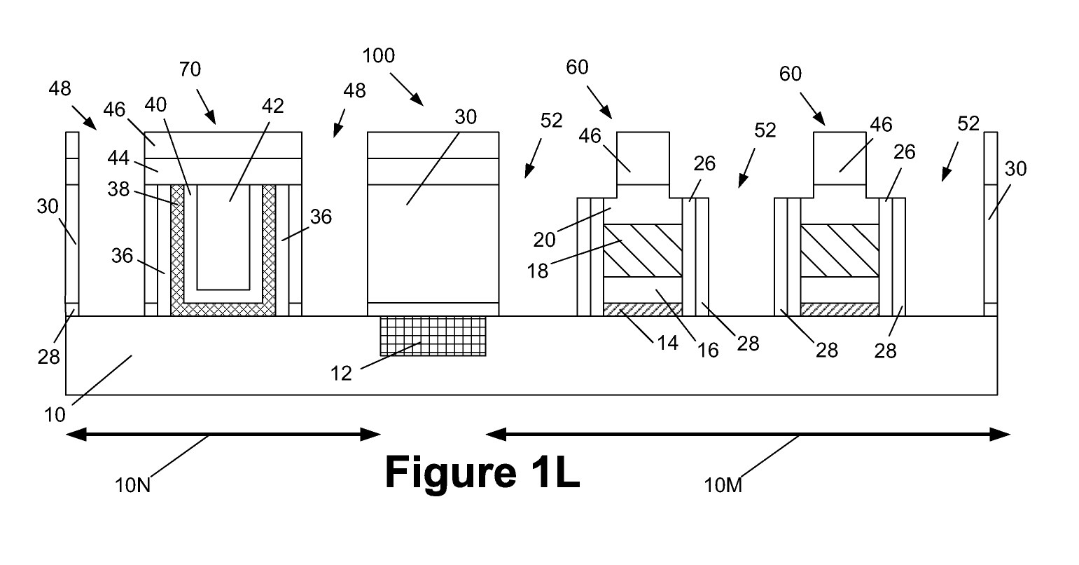

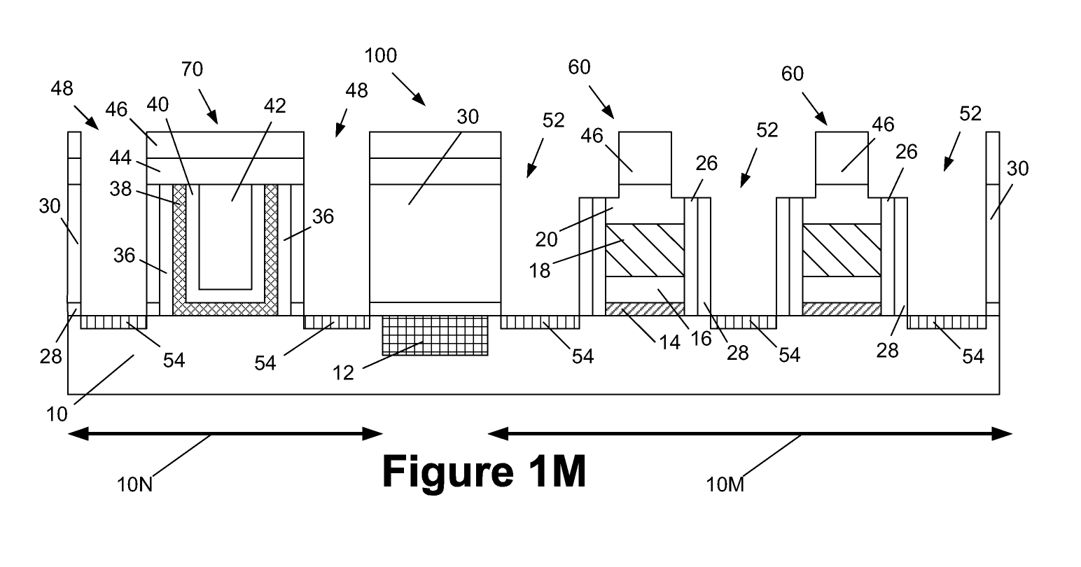

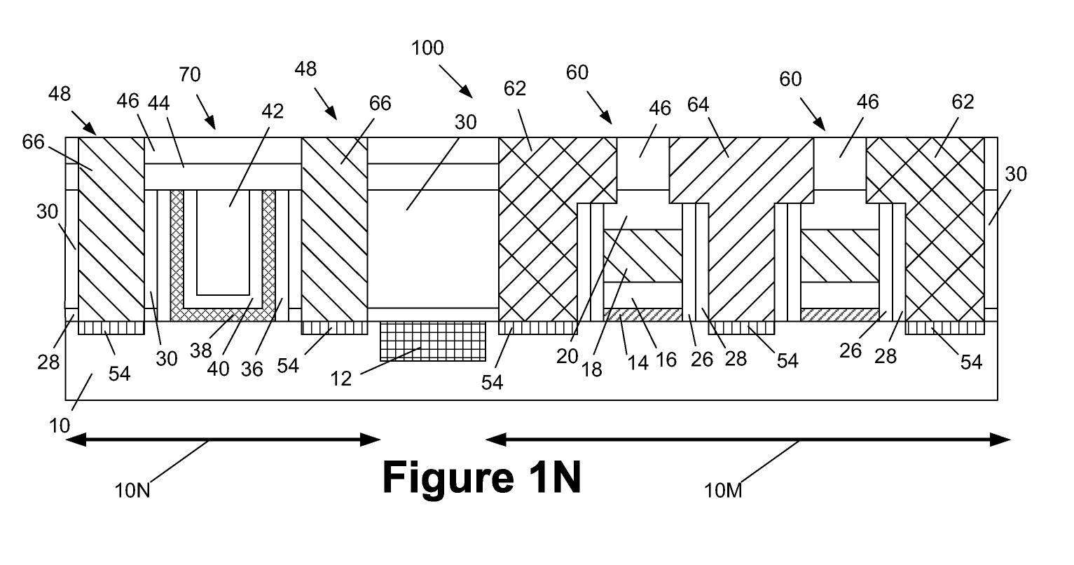

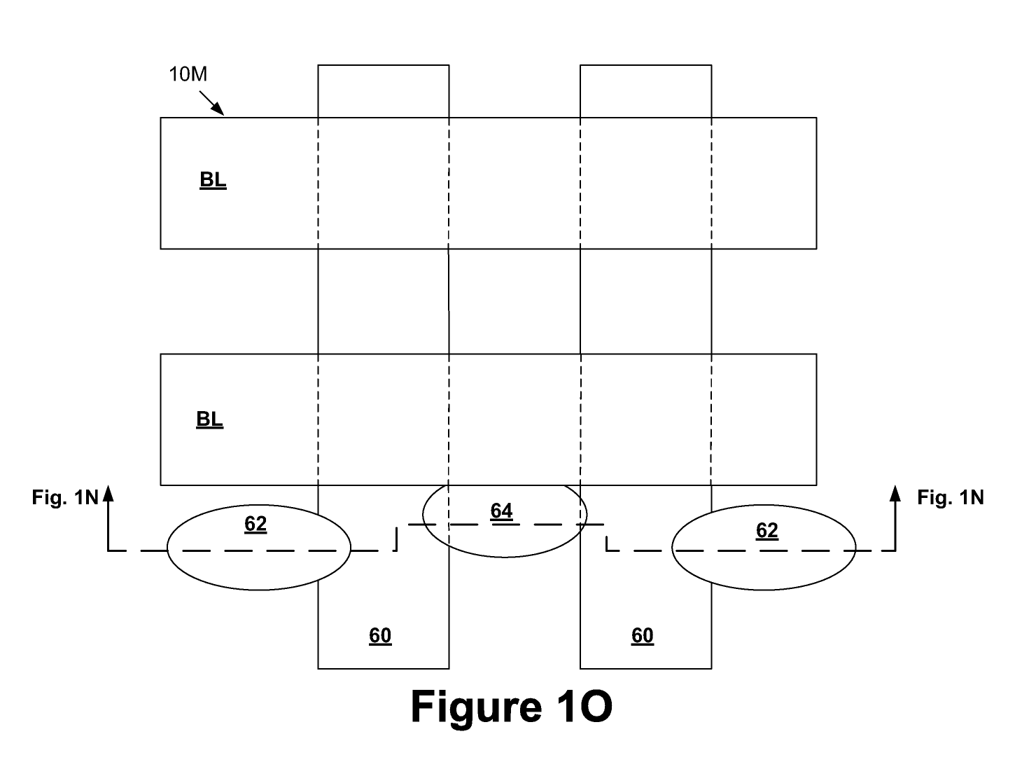

The present disclosure is generally related to a semiconductor device with DRAM word lines and gate electrodes in a non-memory region of the device made of at least one layer of metal, and various methods of making such devices. In one particular embodiment disclosed herein, the word lines (or portions thereof) in the memory array are manufactured at the same time that the sacrificial gate electrode structures for the transistors in the logic circuits of a device are manufactured. Thereafter, the sacrificial gate electrode structures in the non-memory region are removed replaced with a so-called replacement gates using a “gate-last” or “replacement gate” technique. The “gate last” approach is becoming a more popular technique in manufacturing high-performance semiconductor devices, such as high-performance microprocessors, as it permits the device designer to employ metal based electrodes, such as aluminum, lanthanum, titanium nitride, etc., as the material for the gate electrode of the basic transistor device in the logic circuits. Such metal based gate electrode materials when used in combinations with other features, such as the use of so-called “high-k” dielectric materials (k greater than 10), may result in improved performance of integrated circuit devices, such as NMOS and PMOS devices. As will be readily apparent to those skilled in the art upon a complete reading of the present application, the presently disclosed methods and devices are applicable to a variety of technologies, e.g., NMOS, PMOS, CMOS, etc., and they are readily applicable to a variety of devices, including, but not limited to, logic devices, memory devices, etc. With reference to FIGS. 1A-1O, various illustrative embodiments of the methods and devices disclosed herein will now be described in more detail.

As shown in FIG. 1A, the process begins with the formation of various layers of material above the substrate 10. In the illustrative embodiment depicted herein, a layer of insulating material 14, a first metal layer 16, a second metal layer 18, a protective cap layer 20 and a hard mask 22 are blanket-deposited above the substrate 10. A patterned mask layer 24, e.g., photoresist, is also formed above the hard mask 22. The various layers of material may be formed by performing various processes commonly used in manufacturing semiconductor devices, e.g., chemical vapor deposition (CVD), physical vapor deposition (PVD), atomic layer deposition (ALD), a thermal growth process, etc. The various layers may also be made of a variety of different materials and the thickness of each layer may vary depending upon the particular application.

In one illustrative embodiment, the layer of insulating material 14 may have a thickness of approximately 5 nm, and it may be made from any of a variety of different material, e.g., silicon dioxide, silicon oxynitride, a high-k dielectric (k value greater than 10), etc. In one particularly illustrative embodiment, the layer of insulating material 14 may be one of the following high-k dielectrics: tantalum oxide (Ta₂O₅), hafnium oxide (HfO₂), zirconium oxide (ZrO₂), titanium oxide (TiO₂), aluminum oxide (Al₂O₃), hafnium silicates (HfSiOₓ), and the like

The first and second metal layers 16, 18 may be made from a variety of different metals or metal compounds, such as titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi), lanthanum, etc. The first and second metal layers 16, 18 may be deposited using a PVD process. In one illustrative embodiment, the first metal layer 16 may be a layer of titanium nitride with a thickness of about 2-5 nm, and the second metal layer 18 may a layer of tungsten with a thickness of about 20-40 nm. It should also be noted that, at this stage of fabrication, it is not required that there be two metal layers. Rather, in some cases, only a single metal layer may be formed above the layer of insulating material 14.

The protective cap layer 20 may be comprised of a variety of different materials, e.g., silicon nitride, silicon oxynitride, etc. and it may be formed using a CVD process. In one illustrative embodiment, the protective cap layer 20 may be a layer of silicon nitride having a thickness of approximately 20-40 nm. Similarly, the hard mask 22 may be made of a variety of different materials. In one illustrative embodiment, the hard mask 22 is a layer of carbon that is formed using a CVD process or a spin-on process. The patterned mask layer 24, e.g., photoresist, may be formed using traditional photolithography techniques.

Next, multiple etching process are formed on the various layers of material which results in the material stacks, as shown in FIG. 1B. More specifically, the etching processes result in the formation of a sacrificial gate structure 50 in the region 10N and a plurality of word lines 60 in the memory array 10M. In the depicted example, both the sacrificial gate structure 50 and the word lines 60 are comprised of the insulation layer 14 and the first and second metal layers 16, 18. The protective cap layer 20 is positioned above the second metal layer 18. In some cases, the patterned mask layer 24 may be consumed or severely eroded during these etching processes.

FIG. 1C depicts the device 100 after several process steps have been performed. More specifically, sidewall spacers 26 have been formed adjacent the sacrificial gate structure 50 and the word lines 60. The sidewall spacers 26 may be formed by depositing a layer of spacer material, such as silicon nitride, and thereafter performing an anisotropic etching process. After the sidewall spacers 26 are formed, an etch stop liner 28 made of, for example, silicon nitride, is conformally deposited over the device 100. Then, a dielectric material layer 30, such as silicon dioxide, is blanket-deposited on the device 100. A chemical mechanical polishing process (CMP) is performed and stopped on the protective cap layers 20 to result in the structure depicted in FIG. 1C. Also, various doped regions, such as halo implant regions, extension implant regions, etc., may be formed in the substrate adjacent the sacrificial gate structure 50 and/or the word lines 60 at this point in time, by performing known ion implantation processes. However, such doped regions are not depicted in the drawings so as not to obscure the present inventions.

Next, as shown in FIG. 1D, a block mask 32 is formed above the memory array 10M. The block mask 32 should be made of a material that protects the memory array 10M during the subsequent etching of the protective cap layer 20, the sidewall spacers 26 and portions of the liner 28 adjacent the sacrificial gate structure 50. In the depicted example where the sidewall spacers 26 and the liner 28 are made of silicon nitride, the block mask may be made of, for example, silicon dioxide or a siloxane-based material, such as one of the materials sold by Honeywell under the names DUO™ 248, DUO™ 193, and Accufill™ T-28, or it may be a hard mask made of any of a variety of different materials.

FIG. 1E depicts the device 100 after one or more etching processes (wet (preferred) or dry) are performed to remove the protective cap layer 20, the sidewall spacers 26 and portions of the liner 28 adjacent the sacrificial gate structure 50 in the region 10N. FIG. 1F depicts the device 100 after one or more etching processes (wet or dry) are performed to remove the sacrificial gate structure 50, i.e., in the illustrative example depicted herein, the insulation layer 14 and the first and second metal layers 16, 18, to thereby define a gate opening 34 in the dielectric material layer 30.

Next, as shown in FIG. 1G, sidewall spacers 36 are formed in the gate opening 34. The sidewall spacers 36 may be formed by depositing a layer of spacer material, such as silicon nitride, and thereafter performing an anisotropic etching process. In one example, if the block mask 32 remains in place while the spacers 36 are formed, a spacer (not shown) will also be formed adjacent the block mask 32. The block mask 32 and any such spacer formed adjacent to the block mask will eventually be removed, as described more fully below. As an alternative, the block mask 32 may be removed prior to forming the sidewall spacers 36.

At this point, the next activity involves formation of a replacement gate structure in the gate opening 34. More specifically, a layer of insulating material 38 and a metal layer 40 are formed in the gate opening 34 by performing multiple conformal deposition processes. The layer of insulating material 38 may be formed from a variety of different materials, such as those noted above with respect to the insulation layer 14. In one illustrative embodiment, the layer of insulation material 38 is a high-k insulating material. The layers of insulating material 14, 38 may or may not be made of the same insulating material. Similarly, the metal layer 40 may be formed from a variety of different metals or metal compounds, such as those noted above with respect to the first and second metal layers 16, 18. In one illustrative embodiment, the metal layer 40 may be a layer of titanium nitride having a thickness of about 2-5 nm. The metal layer 40 and the first and second metal layer 16, 18 may or may not be made of the same metal. In this illustrative embodiment, the replacement or final gate structure for the transistor device in the logic region 10N has a plurality of U-shaped layers of material, such as the layer of insulating material 38 and the metal layer 40. This U-shaped configuration for the layers of material in the final gate structure in the logic region 10N is in contrast to the substantially planar layers 14, 16 and 18 that make up the word line 60 in the memory array 10M.

Next, as shown in FIGS. 1I-1J, a metal layer 42 is deposited above the device 100 and in the gate opening 34 and a CMP process is performed that stops on the protective cap layers 20 in the memory array 10M. During this CMP process, the block mask 32 and the excess portions of the metal layers 40, 42 and the insulation layer 38 positioned outside the gate opening 34 are removed. This results in the definition a final or replacement gate structure 70 for the transistor that is to be formed in the region 10N. The metal layer 42 may be comprised of any of the metal or metal compound, such as those identified above with respect to the first and second metal layers 16, 18. In the illustrative example depicted herein, the replacement gate structure 70 is comprised of portions of the conformally deposited layer of insulating material 38, the conformally deposited metal layer 40 and the metal layer 42. As will be recognized by those skilled in the art after a complete reading of the present application, the insulating materials and the metal layer(s) that are part of the replacement gate structure 70 may be of any desired construction and comprised of any of a variety of different materials. Additionally, the replacement gate structure 70 for a NMOS device may have different material combinations as compared to a replacement gate structure 70 for a PMOS device. Thus, the particular details of construction of replacement gate structure 70, and the manner in which such replacement gate electrode structure 70 is formed, should not be considered a limitation of the present invention unless such limitations are expressly recited in the attached claims.

Next, as shown in FIG. 1K, a mask layer 44, e.g., silicon nitride, is formed to protect the replacement gate structures 70 in the region 10N. The mask layer 44 may be formed by depositing a layer of material and then patterning that layer of material using techniques that are well known to those skilled in the art. After the mask layer 44 is formed, a layer of insulating material 46, e.g., silicon dioxide, may be deposited above the device 100 and a CMP process is performed to result in the structure depicted in FIG. 1K.

The next step in manufacturing the device 100, involves forming conductive contacts to various doped regions, i.e., source/drain regions, that have previously been formed in the substrate 10 by performing known ion implantation techniques. However, such doped regions are not depicted in the drawings so as not to obscure the present invention. As shown in FIG. 1L, this process begins with performing one or more etching processes to etch through the layer of dielectric material 30 and the etch stop layer 28 to thereby form contact openings 48 in the region 10N and contact openings 52 in the memory array 10M. In one illustrative embodiment, the contact openings 48, 52 are formed by performing an anisotropic reactive ion etching (RIE) process, although other etching techniques might also be employed. In the illustrative case where the sidewall spacers 26 and the liner 28 in the memory array 10M are comprised of silicon nitride, the etching chemistry should be such that there is a 1:5-1:10 etch selectivity relative to silicon nitride. In one particular example, etchants such as C₅F₈ or C₄F₆ may be used in forming the openings 48, 52. Note that, using the novel methods disclosed herein, the contact openings 52 permit the formation of self-aligned conductive contacts in the memory array 10M, as described more fully below, thereby further reducing the physical size of the memory array 10M.

Next, as shown in FIG. 1M, metal silicide regions 54 are formed at the bottom of the contact openings 48, 52 to facilitate electrical connection to underlying doped regions (not shown), such as source/drain regions, formed in the substrate 10. The metal silicide regions 54 may be formed using known techniques and any of a variety of different refractory metals may be employed, e.g., nickel, platinum, cobalt, titanium, or combinations thereof, etc. If desired, the metal silicide regions 54 may all be of the same metal silicide or they may be different metal silicides.

As shown in FIG. 1N, the next step involves forming conductive contacts in the contact openings 48, 52. More specifically, a pair of illustrative capacitor contacts 62 and an illustrative bit line contact 64 are formed in the memory array 10M, while illustrative source/drain conductive contacts 66 are formed for the transistor in the region 10N. FIG. 1O is a plan view of a portion of the illustrative memory array 10M, wherein a plurality of bit lines (“BL”) and word lines 60 are depicted along with the illustrative capacitor contacts 62 and the illustrative bit line contact 64. The view depicted in FIG. 1N is depicted in FIG. 1O. As noted earlier, the conductive contacts 62, 64 in the memory array 10M are self-aligned in the sense that at least a portion of the contact opening, e.g., the contact opening 52 for the bit line contact 64, is defined by an etching process and not by direct photolithography patterning, i.e., the final dimension at the bottom of the contact opening is smaller, and sometimes much smaller, than the initial critical dimension of the contact opening as established by direct photolithography. More specifically, in the case of the contact opening 52 for the bit line contact 64, the etching process and chemistry removes the dielectric material layer 30 selective to the silicon nitride etch stop layer 28, the silicon nitride cap layer 20 and the substrate 10 to thereby define the size and shape of the final bit line contact 64. Once the etching process to form the contact openings 48, 52 proceeds to the point where it reaches the silicon nitride etch stop layer 28, the etching chemistry is changed and a very short “breakthrough” etching process is performed to remove the exposed portions of the silicon nitride etch stop layer 28 within the openings 48, 52 to thereby expose the underlying substrate and permit the formation of the metal silicide regions 54 described above. The conductive contacts 62, 64 and 66 may be made of a variety of materials, such as tungsten, copper, aluminum, etc., and different materials may be used for the conductive contacts in the memory array 10M as compared to the materials used in the region 10N. The conductive contacts 62, 64, 66 may also include one or more barrier layers, such as a dual layer of titanium/titanium nitride, tantalum nitride (for copper contacts), etc., although such barrier layers are not depicted in the drawings so as not to obscure the present invention. The conductive contacts 62, 64, 66 may be formed using traditional techniques, such as by performing one or more deposition processes to fill the contact openings and thereafter performing a CMP process to remove excess material positioned outside of the contact openings.

At the point depicted in FIG. 1N, various additional processing operations may be performed to complete the formation of the device 100, such as the formation of additional metallization layers including, for example, bit lines (shown in FIG. 1O) in the memory array 10M using known techniques. Of course, the total number of metallization layers may vary depending on the particular device under construction. One or more of the problems discussed in the background section of the application may be eliminated or at least reduced using the methods and devices disclosed herein.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor device comprising a memory array and a logic region, comprising:
forming a sacrificial gate electrode structure in said logic region and a word line in said memory array, each of said sacrificial gate electrode structure and said word line comprising a first layer of insulating material and at least one first layer comprising a metal;
removing said sacrificial gate electrode structure in said logic region to define a gate opening; and
forming a final gate electrode structure in said gate opening.

2. The method of claim 1, wherein removing said sacrificial gate electrode structure comprises performing at least one etching process to remove said sacrificial gate electrode structure.

3. The method of claim 1, wherein forming said final gate electrode structure in said gate opening comprises performing a conformal deposition process to deposit a second layer of insulating material in said gate opening and performing a conformal deposition process to deposit at least one second layer comprising a metal on said second layer of insulating material.

4. The method of claim 1, wherein forming said sacrificial gate electrode structure in said logic region and said word line in said memory array comprises:
blanket-depositing said first layer of insulating material;
blanket-depositing said at least one first layer comprising a metal on said first layer of insulating material;
forming a patterned mask layer above said at least one first layer comprised of metal; and
performing at least one etching process on said at least one first layer comprising a metal and said first layer of insulating material through said mask layer to define said sacrificial gate electrode structure and said word line.

5. The method of claim 4, wherein said first layer of insulating material and said second layer of insulating material are each comprised of a high-k insulating material.

6. The method of claim 3, wherein said first layer of insulating material and said second layer of insulating material are each comprised of the same material.

7. The method of claim 3, wherein said first layer comprising a metal and said second layer comprising a metal are each comprised of the same metal or metal compound.

8. The method of claim 3, wherein said first layer comprising a metal and said second layer comprising a metal are each comprised of different metals or metal compounds.

9. The method of claim 1, further comprising forming at least one self-aligned contact between said word line and a doped region in a semiconducting substrate positioned below said word line.

10. A method of forming a semiconductor device comprising a memory array and a logic region, comprising:
forming a sacrificial gate electrode structure in said logic region and a word line in said memory array, each of said sacrificial gate electrode structure and said word line comprising a first layer of insulating material and at least one first layer comprising a metal, by:
blanket-depositing said first layer of insulating material;
blanket-depositing said at least one first layer comprising a metal on said first layer of insulating material;
forming a patterned mask layer above said at least one first layer comprised of metal; and
performing at least one etching process on said at least one first layer comprising a metal and said first layer of insulating material through said mask layer to define said sacrificial gate electrode structure and said word line;
removing said sacrificial gate electrode structure in said logic region to define a gate opening; and
forming a final gate electrode structure in said gate opening by:
performing a conformal deposition process to deposit a second layer of insulating material in said gate opening; and
performing a conformal deposition process to deposit at least one second layer comprising a metal on said second layer of insulating material.

11. The method of claim 10, wherein said first layer comprising a metal and said second layer comprising a metal are each comprised of the same metal or metal compound.

12. The method of claim 11, wherein said first layer of insulating material and said second layer of insulating material are each comprised of the same material.

13. The method of claim 10, further comprising forming at least one self-aligned contact between said word line and a doped region in a semiconducting substrate positioned below said word line.

14. A device comprising a memory array and a logic region, the device comprising:
a word line in said memory array, said word line comprising a first layer of insulating material and at least one first layer comprising a metal;
a replacement gate electrode structure in said logic region, said replacement gate electrode structure comprising a conformally deposited second layer of insulating material and a conformally deposited second layer comprising a metal positioned on said second layer of insulating material.

15. The device of claim 14, wherein said first layer comprising a metal and said second layer comprising a metal are comprised of the same material.

16. The device of claim 14, wherein said first layer comprising a metal and said second layer comprising a metal are comprised of different materials.

17. The device of claim 14, wherein both of said first and second layers of insulating material are comprised of a high-k insulating material.

18. The device of claim 14, further comprising at least one self-aligned contact between said word line and a doped region in a semiconducting substrate positioned below said word line.

19. A device comprising a memory array and a logic region, the device comprising:
a word line in said memory array, said word line comprising a first substantially planar layer of insulating material and at least one first substantially planar layer comprising a metal;
a replacement gate electrode structure in said logic region, said replacement gate electrode structure comprising a substantially U-shaped layer of insulating material and a substantially U-shaped second layer comprising a metal positioned on said substantially U-shaped of insulating material.

20. The device of claim 19, further comprising at least one self-aligned contact between said word line and a doped region in a semiconducting substrate positioned below said word line.
